(19) United States
(12) Patent Application Publication
(10) Pub. No.: US 2024/0088078 A1
(43) Pub. Date: Mar. 14, 2024

(54) Packaged Memory Device and Method

(71) Applicant: Taiwan Semiconductor Manufacturing Co., Ltd., Hsinchu (TW)

(72) Inventors: Chung-Hao Tsai, Huatan Township (TW); Yih Wang, Hsinchu (TW); Wei-Ting Chen, Tainan City (TW); Chuei-Tang Wang, Taichung City (TW); Chen-Hua Yu, Hsinchu (TW)

(21) Appl. No.: 18/150,034

(22) Filed: Jan. 4, 2023

Related U.S. Application Data
(60) Provisional application No. 63/375,263, filed on Sep. 12, 2022.

(51) Int. Cl. H01L 23/00; H01L 25/00; H01L 25/065; H01L 25/18

(52) U.S. Cl. CPC H01L 24/08; H01L 24/80; H01L 25/0657; H01L 25/18; H01L 25/50; H01L 2224/08145; H01L 2224/80895; H01L 2224/80896; H01L 2924/1431; H01L 2924/1437

(57) ABSTRACT

Packaged memory devices including memory devices hybrid bonded to logic devices and methods of forming the same are disclosed. In an embodiment, a semiconductor device includes a first memory die including a first memory cell electrically coupled to a first word line; a second memory cell electrically coupled to the first word line; and a first interconnect structure electrically coupled to the first word line; a circuitry die including a second interconnect structure, a first conductive feature of the first interconnect structure being bonded to a second conductive feature of the second interconnect structure through metal-to-metal bonds; and a word line driver electrically coupled to the first word line between the first memory cell and the second memory cell, the word line driver being electrically coupled to the first word line through the first interconnect structure and the second interconnect structure.

### PRIORITY CLAIM

This application claims the benefit of U.S. Provisional Application No. 63/375,263, filed on Sep. 12, 2022, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of a static random access memory (SRAM) cell, in accordance with some embodiments.

FIG. 2 illustrates a cross-sectional view of layers of an SRAM cell array, in accordance with some embodiments.

FIG. 3 illustrates a block diagram of an SRAM cell layout, in accordance with some embodiments.

FIGS. 4 through 8 illustrate block diagrams of an SRAM memory array layout, in accordance with some embodiments.

FIG. 9 illustrates a cross-sectional view of a memory device, in accordance with some embodiments.

FIG. 10 illustrates a cross-sectional view of a logic device, in accordance with some embodiments.

FIG. 11 illustrates a cross-sectional view of a memory device bonded to a logic device, in accordance with some embodiments.

FIG. 12 illustrates a perspective view of a memory device bonded to a logic device, in accordance with some embodiments.

FIG. 13 illustrates a cross-sectional view of multiple memory devices bonded to a logic device, in accordance with some embodiments.

FIGS. 14A and 14B illustrate block diagrams of bond pad layouts for an SRAM memory array, in accordance with some embodiments.

FIGS. 15 and 16 illustrate cross-sectional views of packaged semiconductor devices, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor memory devices having improved architectures and methods of forming the same. The memory devices may be formed by forming a memory device, forming a circuitry device, and bonding the memory device and the circuitry device. The memory device may include a plurality of memory cells. The circuitry device may include a plurality of functional circuits, such as decoders, processors, multiplexors, controllers, sense amplifiers, drivers (e.g., word line drivers, bit line drivers, and the like), and the like, which may be used to provide read/write operations and otherwise control the memory cells of the memory device. The memory device may be free from functional circuits, or may have a reduced number of functional circuits, as the functional circuits for the memory device are provided by the circuitry device. The memory device and the circuitry device may be bonded by system on integrated chip (SoIC) technology, such as hybrid bonding or the like. In some embodiments, a plurality of memory devices may be bonded to a single circuitry device. Bonding the memory device directly to the circuitry device simplifies routing between the memory device and the circuitry device, shortens the length of contacts and conductive lines used to route connections between the memory device and the circuitry device, reduces contact resistance, reduces latency, reduces power usage, and improves device performance.

Embodiments are described below in a particular context, namely, a semiconductor devices comprising fin field-effect transistors (FinFETs). Various embodiments may be applied, however, to dies comprising other types of transistors (e.g., nanostructure field-effect transistors (nanostructure FETs), complementary field effect transistors (CFETs), thin film transistors (TFTs), planar transistors, or the like) in lieu of or in combination with the FinFETs.

Static random access memory (SRAM) cells are provided in accordance with various embodiments. Some variations of particular embodiments are discussed. Throughout the various views and illustrative embodiments, like reference numbers are used to designate like elements formed using like processes. Furthermore, although various embodiments are described in a particular context of SRAM layouts, other embodiments may also be applied to other memory cell configurations, such as read only memory (ROM) cells, dynamic random access memory (DRAM) cells, magnetic random access memory (MRAM) cells, phase change random access memory (PRAM) cells, resistive random access memory (RRAM) cells, and the like.

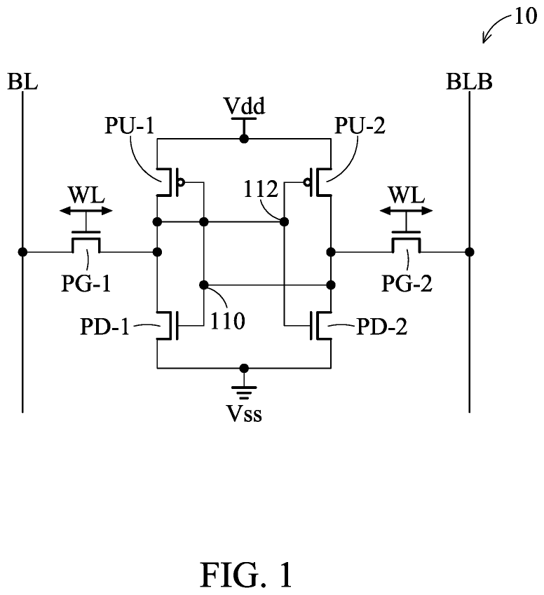

FIG. 1 illustrates a circuit diagram of a SRAM cell 10 in accordance with some embodiments. The SRAM cell 10 includes pull-up transistors PU-1 and PU-2, pull-down transistors PD-1 and PD-2, and pass-gate transistors PG-1 and PG-2. The pull-up transistors PU-1 and PU-2 may be P-type metal-oxide-semiconductor (PMOS) transistors. The pull-down transistors PD-1 and PD-2 and the pass-gate transistors PG-1 and PG-2 may be N-type metal-oxide-semiconductor (NMOS) transistors. The gates of PG transistors PG-1 and PG-2 are controlled by a word line WL that determines whether the SRAM cell 10 is selected or not. A latch formed of the pull-up transistors PU-1 and PU-2 and the pull-down transistors PD-1 and PD-2 stores a bit. The complementary values of the bit are stored in storage data (SD) nodes 110 and 112. The stored bit can be written into or read from the SRAM cell 10 through complementary bit lines including bit line BL and bit line bar BLB. The SRAM cell 10 is powered through a positive power supply voltage line Vdd. The SRAM cell 10 is also connected to a power supply voltage line Vss, which may be an electrical ground. The pull-up transistor PU-1 and the pull-down transistor PD-1 form a first inverter. The pull-up transistor PU-2 and the pull-down transistor PD-2 form a second inverter. The input of the first inverter is connected to the pass-gate transistor PG-1 and the output of the second inverter. The output of the first inverter is connected to the pass-gate transistor PG-2 and the input of the second inverter.

The sources of the pull-up transistors PU-1 and PU-2 are connected to the power supply voltage line Vdd. The sources of the pull-down transistors PD-1 and PD-2 are connected to the power supply voltage line Vss. The gates of the pull-up transistor PU-1 and the pull-down transistor PD-1 are connected to the drains of the pull-up transistor PU-2 and the pull-down transistor PD-2, which form the storage data node 110. The gates of the pull-up transistor PU-2 and the pull-down transistor PD-2 are connected to the drains of the pull-up transistor PU-1 and the pull-down transistor PD-1, which form the storage data node 112. A source/drain region of the pass-gate transistor PG-1 is connected to the bit line BL. A source/drain region of the pass-gate transistor PG-2 is connected to the bit line bar BLB.

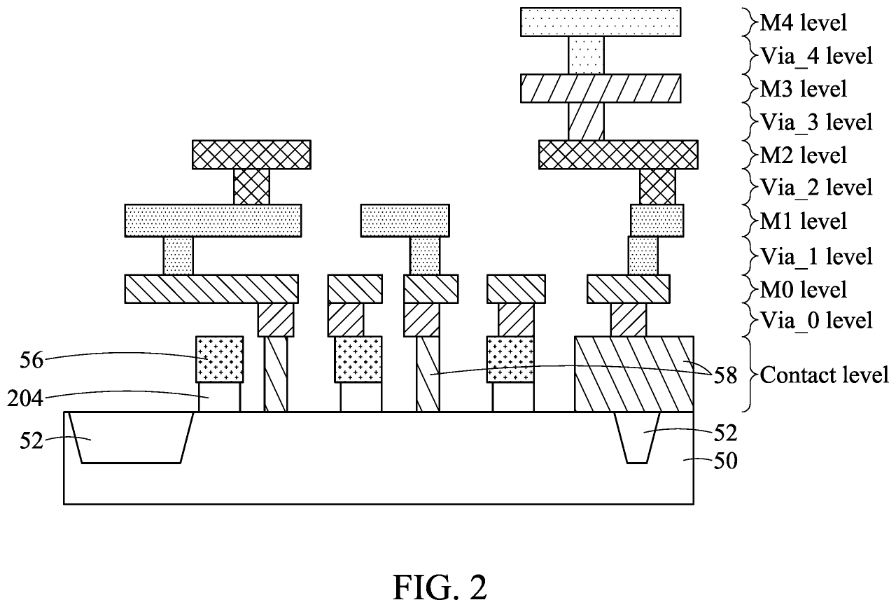

FIG. 2 illustrates a schematic cross-sectional view of a plurality of layers that may be included in the SRAM cell 10. It is noted that FIG. 2 is schematically illustrated to show various levels of an interconnect structure and transistors, and may not reflect an actual cross-sectional view of an SRAM cell 10. The interconnect structure includes an OD (oxide definition or active area) level; a contact level; a plurality of via levels including a Via_0 level, a Via_1 level, a Via_2 level, a Via_3 level, and a Via_4 level; and a plurality of metal-layer levels M1 level, M2 level, M3 level, and M4 level. Each of the illustrated levels includes one or more dielectric layers and the conductive features formed therein. The conductive features that are at the same level may have top surfaces substantially level to each other, bottom surfaces substantially level to each other, and may be formed simultaneously.

The SRAM cell 10 may be formed on a substrate 50. The substrate 50 may be a semiconductor substrate, such as a bulk semiconductor, a semiconductor-on-insulator (SOI) substrate, or the like, which may be doped (e.g., with p-type or n-type dopants) or un-doped. The substrate 50 may be a wafer, such as a silicon wafer or a single die (e.g., processed in a wafer and then removed from other devices of the wafer using a singulation process). STI regions 52 may be formed in the substrate 50 to isolate adjacent SRAM cells 10 from one another. The contact level may include gate contacts 56 (also referred to as contact plugs) for connecting gate electrodes 204 of the transistors of the SRAM cell 10 to overlying levels, such as the Via_1 level, and source/drain contacts 58 for connecting source/drain regions of the transistors to the overlying levels.

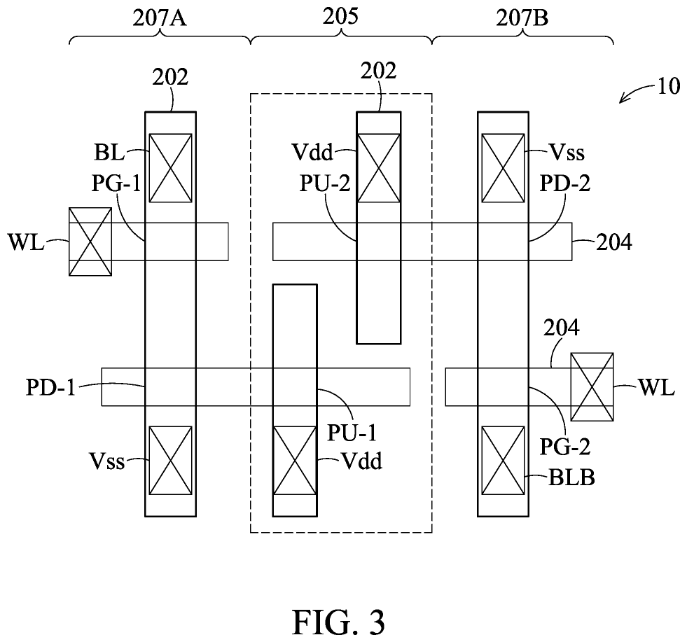

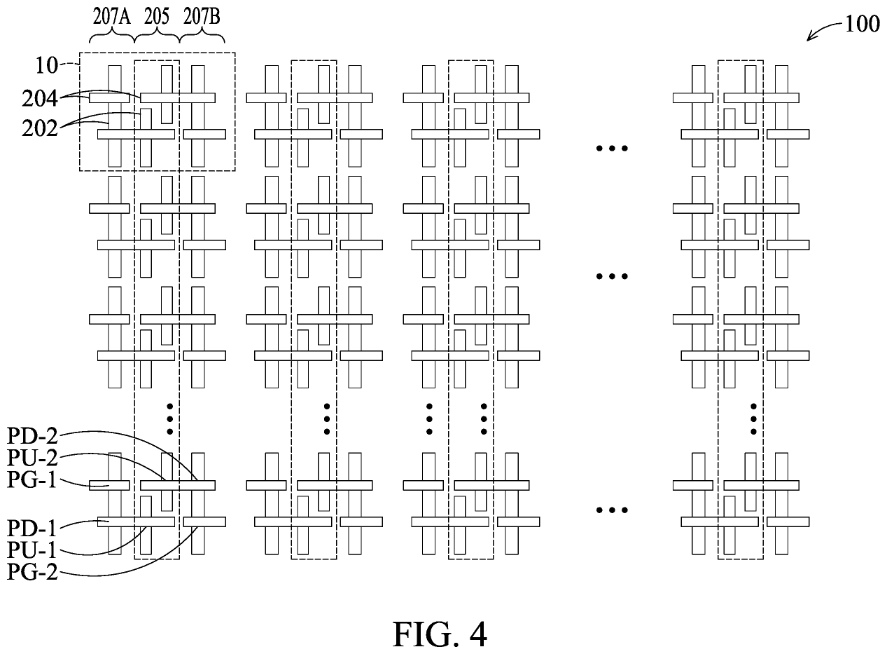

FIG. 3 illustrates a block diagram of a layout of features of a memory cell (e.g., an SRAM cell 10), in accordance with some embodiments. FIGS. 4 through 8 illustrate block diagram of layouts of features of a memory array 100 including a plurality of memory cells (e.g., a plurality of SRAM cells 10). Features in FIGS. 3 through 8 are illustrated in different levels of the memory array 100, (e.g., an OD level, an M0 level, an M1 level, M2/M3 levels, and an M4 level), and are consecutively described for clarity.

FIG. 3 illustrates a layout of an SRAM cell 10 in the OD level. The SRAM cell 10 may include an n-well region 205 and two p-well regions 207A and 207B on opposite sides of the n-well region 205. Fin structures 202 are formed parallel with one another. Gate electrodes 204 are formed parallel with one another and perpendicular to the fin structures 202. The gate electrodes 204 cross over underlying fin structures 202, and are the pass-gate transistors PG-1 and PG-2, the pull-down transistors PD-1 and PD-2, and the pull-up transistors PU-1 and PU-2 formed at the intersections of the gate electrodes 204 and the fin structures 202.

FIGS. 3 and 4 illustrate features in the OD level (see FIG. 2) and the overlying gate electrodes 204 of various transistors in the SRAM cells 10. An n-well region 205 is formed in the middle of each of the SRAM cells 10 and two p-well regions 207A and 207B are on opposite sides of the n-well region 205. Each of the gate electrodes 204 forms a transistor with an underlying active region. In an embodiment, the active regions are fin-based and include one or more fin structures 202 disposed under the gate electrodes 204 (e.g., the gate electrodes 204 may be on and extending along side surfaces and top surfaces of the fin structures 202).

In some embodiments, the pass-gate transistors PG-1 and PG-2, the pull-up transistors PU-1 and PU-2, and the pull-down transistors PD-1 and PD-2 are FinFETs, as described above where the active regions include one or more fin structures 202. In some embodiments, one or more of the pass-gate transistors PG-1 and PG-2, the pull-up transistors PU-1 and PU-2, and the pull-down transistors PD-1 and PD-2 may be planar MOS devices having active regions doped in an upper surface of a semiconductor substrate. The active regions may provide source/drains of the transistors on opposing sides of respective gate electrodes 204. In FIG. 3, a single fin structure 202 is provided for each of the active regions. In some embodiments, multiple fins may be provided for each of the active regions, and the number of fins provided for each of the active regions may be the same or different within the SRAM cell 10.

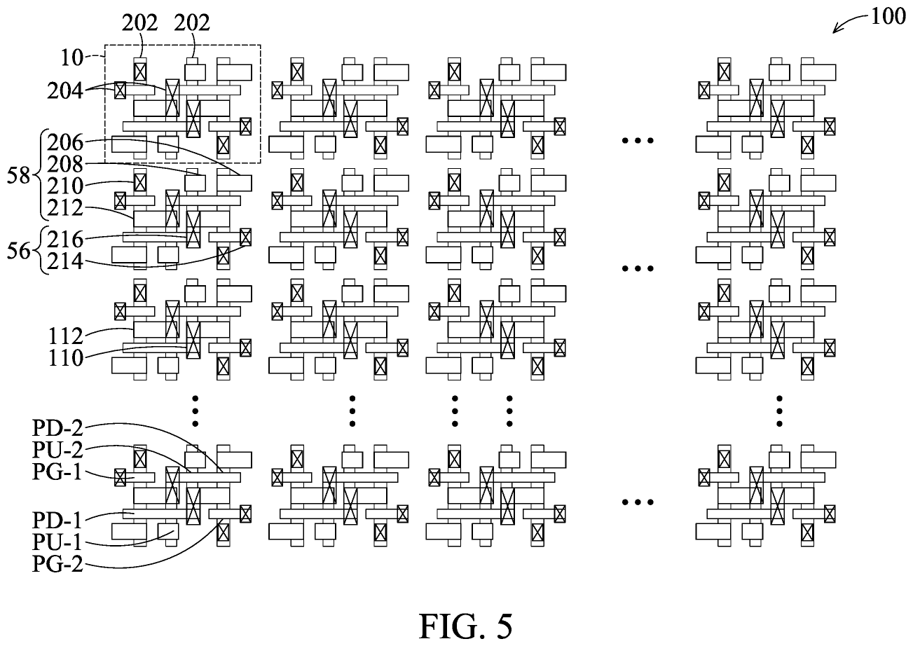

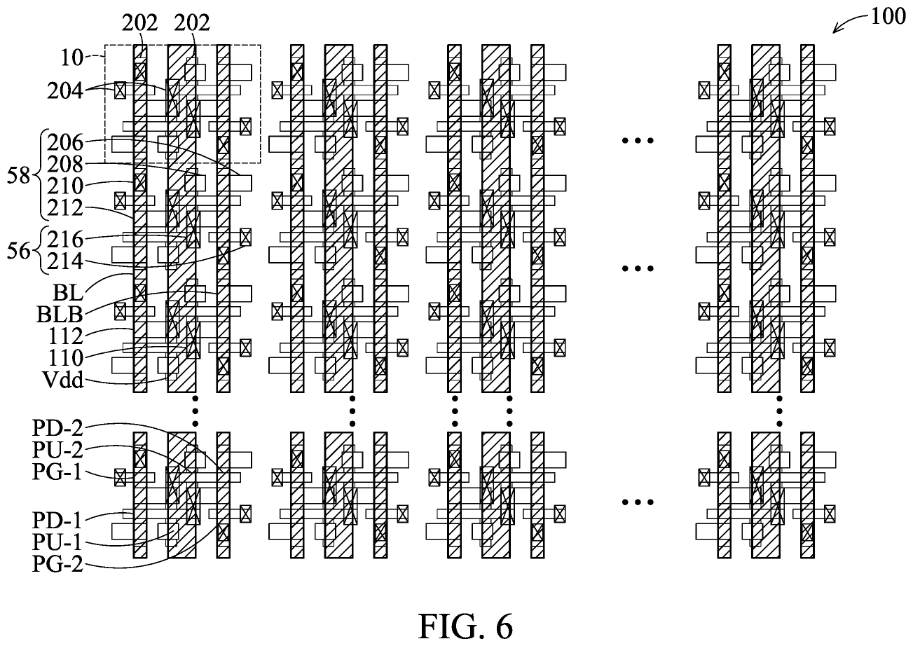

FIG. 5 illustrates features of the memory array 100 in the contact level (see FIG. 2) and lower. As illustrated in FIG. 6B, the storage data node 110 (see also FIG. 1) and the storage data node 112 include source/drain contacts 212 (also referred to as contact plugs) and gate contacts 216, which are the features at the contact level of the SRAM cells 10 (see FIG. 3). The source/drain contacts 212 may be used to electrically couple source/drain regions of the pull-down transistors PD-1 and PD-2 and the pull-up transistors PU-1 and PU-2 to the gate electrodes 204. The source/drain contacts 212 may be elongated and have longitudinal directions parallel to longitudinal directions of the gate electrodes 204. The gate contacts 216 may include portions over and electrically coupled to the gate electrodes 204. In some embodiments, the gate contacts 216 have longitudinal directions perpendicular to the longitudinal directions of the gate electrodes 204. In some embodiments, the source/drain contacts 212 and the gate contacts 216 may be formed as single continuous butted contacts.

Gate contacts 214 may also be electrically coupled to the gate electrodes 204. The gate contacts 214 may be used to electrically couple the gate electrodes 204 to one or more word lines WL. Source/drain contacts 206 may be used to electrically couple source/drain regions of the pull-down transistors PD-1 and PD-2 to the power supply voltage line Vss (e.g., electrical ground lines). The source/drain contacts 206 may be elongated and have longitudinal directions parallel to longitudinal directions of the gate electrodes 204. The source/drain contacts 206 may overlap corners of the SRAM cells 10. The source/drain contacts 206 may extend into neighboring SRAM cells 10 in a different column that abut an SRAM cell 10. The source/drain contacts 206 may be shared between two neighboring SRAM cells 10. Source/drain contacts 208 may be used to electrically couple source/drain regions of the pull-up transistors PU-1 and PU-2 to the power supply voltage line Vdd (e.g., supply voltage lines). The source/drain contacts 208 may be shared between two neighboring SRAM cells 10. Source/drain contacts 210 may be used to electrically couple source/drain regions of the pass-gate transistors PG-1 and PG-2 to a bit line BL and a bit line bar BLB. The source/drain contacts 210 may be shared between two neighboring SRAM cells 10. The gate contacts 56 illustrated in FIG. 2 include the gate contacts 214 and the gate contacts 216. The source/drain contacts 58 illustrated in FIG. 2 include the source/drain contacts 206, the source/drain contacts 208, the source/drain contacts 210, and the source/drain contacts 212.

FIG. 6 illustrates features of the memory array 100 in the M0 level (see FIG. 2) and lower. In FIG. 6, bit lines BL, bit lines bar BLB, and power supply voltage lines Vdd are disposed in the M0 level. Conductive vias may be included in the via_0 level to couple the bit lines BL and the bit lines bar BLB to the source/drain contacts 210 (e.g., source/drain contacts of the pass-gate transistors PG-1 and PG-2). SRAM cells 10 in a same column within the memory array 100 may share a continuous bit line BL and a continuous bit line bar BLB. For example, the portion of the bit line BL and the bit line bar BLB each SRAM cell 10 may be connected to portions of bit line BL and the bit line bar BLB in other SRAM cells 10 within the same column to form a continuous bit line BL and a continuous bit line bar BLB for each column of the memory array 100. The source/drain contacts 210 of the pass-gate transistors PG-1 and PG-2 of SRAM cells 10 in different columns are electrically coupled bit lines BL and bit lines bar BLB that are electrically isolated from bit lines BL and bit lines bar BLB of different columns.

Conductive vias may be included in the via_0 level to couple the power supply voltage lines Vdd to the source/drain contacts 208 (e.g., source/drain contacts of the pull-up transistors PU-1 and PU-2). SRAM cells 10 in a same column within the memory array 100 may share a continuous power supply voltage line Vdd. The source/drain contacts 208 of the pull-up transistors PU-1 and PU-2 of SRAM cells 10 in different columns may be electrically coupled to power supply voltage lines Vdd that are electrically isolated from power supply voltage lines Vdd of different columns.

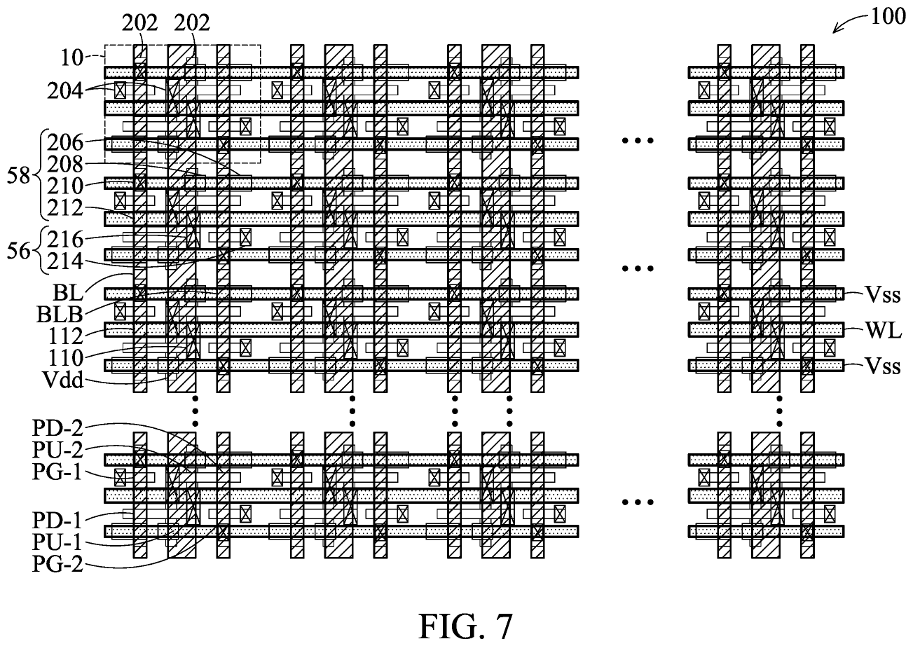

FIG. 7 illustrates features of the memory array 100 in the M1 level (see FIG. 2) and lower. In FIG. 7, word lines WL and power supply voltage lines Vss are disposed in the M2 level. Conductive vias may be included in the via_1 level, conductive lines may be included in the M0 level, and conductive vias may be included in the via_0 level to couple the word lines WL to the gate contacts 214 (e.g., gate contacts for the pass-gate transistors PG-1 of PG-2). SRAM cells 10 in a same row within the memory array 100 may share a continuous word line WL, which is used to select or deselect SRAM cells 10 in the memory array 100. For example, in order to select a particular SRAM cell 10, a positive voltage may be applied to a bit line BL or a bit line bar BLB and a word line WL corresponding to the SRAM cell 10.

Conductive vias may be included in the via_1 level, conductive lines may be included in the M0 level, and conductive vias may be included in the via_0 level to couple the power supply voltage lines Vss to the source/drain contacts 206 (e.g., source/drain contacts for the pull-down transistors PD-1 or PD-2). SRAM cells 10 in a same row within the memory array 100 may share one or more continuous power supply voltage lines Vss.

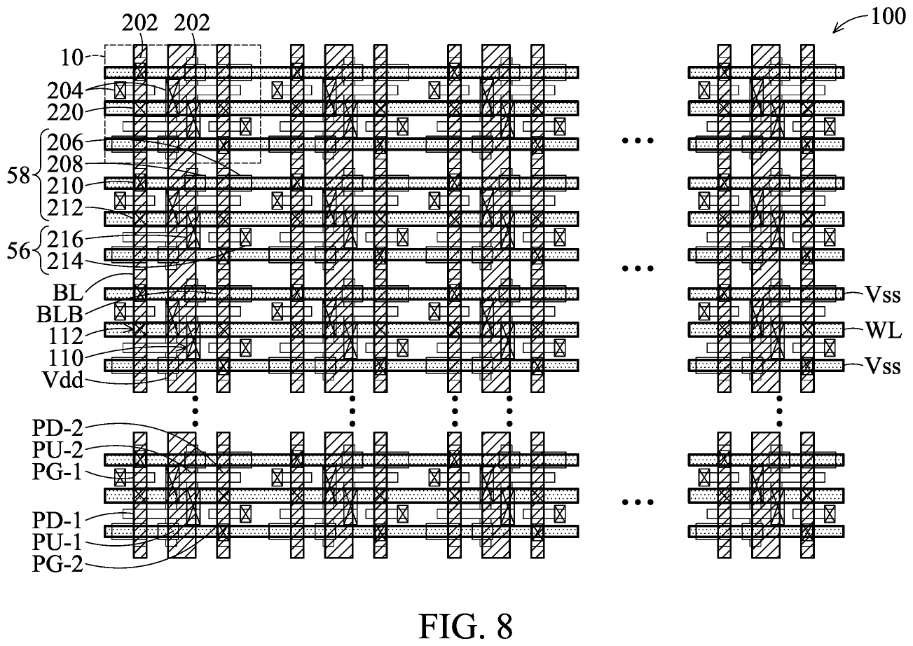

FIG. 8 illustrates features of the memory array 100 in the M4 level (see FIG. 2) and lower. In FIG. 8, bond pads 220 are disposed in the M4 level. As illustrated in FIG. 8, the bond pads 220 may be disposed above intersections of the word lines WL and the bit lines BL or the bit lines bar BLB. However, in some embodiments, the bond pads 220 may be disposed anywhere in the M4 level as desired, and connections between the bond pads 220 and desired underlying lines may be routed through conductive lines and conductive vias provided in the underlying metal layers (e.g., the M2 level, the M3 level, the via_2 level, and the via_3 level). The bond pads 220 may provide connections between the SRAM cells 10 of the memory array 100, and external devices, such as circuitry devices, logic devices, peripheral devices, memory devices, power management devices, RF devices, sensor devices, MEMS devices, signal processing devices, front-end devices, the like, or combinations thereof. The external devices may include functional circuits, and may be used to control reading, writing, and the like for the memory array 100. The bond pads 220 may be electrically coupled to the word lines WL, the bit lines BL, the bit lines bar BLB, and the like. The bond pads 220 may be electrically coupled to any intermediate portions of the word lines WL, the bit lines BL, the bit lines bar BLB, rather than being electrically coupled to ends of the word lines WL, the bit lines BL, the bit lines bar BLB. This provides for greater flexibility of the routing of various connections through the SRAM cells 10 of the memory array 100, shortens the lengths of connections between the functional circuits of the external devices and the word lines WL, the bit lines BL, the bit lines bar BLB, and provides improved latency and power use. The memory array 100 may be free from functional circuits, which allows for a higher density of SRAM cells 10 to be included in the memory array 100.

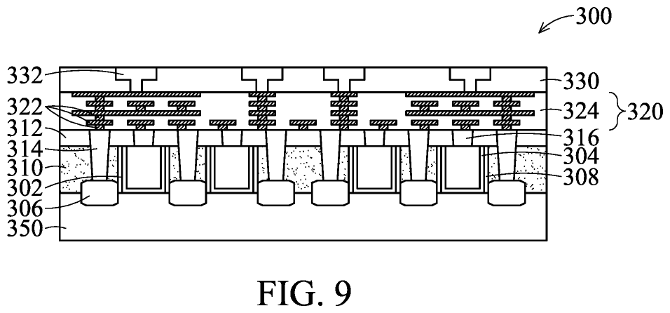

FIG. 9 illustrates a cross-sectional view of a semiconductor device 300. The semiconductor device 300 may be a memory device, such as the memory array 100, discussed above. The semiconductor device 300 may include circuits formed on a substrate 350. The substrate 350 may be a semiconductor substrate, such as a bulk semiconductor, a semiconductor-on-insulator (SOI) substrate, or the like, which may be doped (e.g., with a p-type or an n-type dopant) or un-doped. The substrate 350 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or a glass substrate. Other substrates, such as multi-layered or gradient substrates may also be used. In some embodiments, the semiconductor material of the substrate 350 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The circuits formed on the substrate 350 may include transistors at a top surface of the substrate 350. The transistors may include gate dielectric layers 302 on top surfaces of the substrate 350 and gate electrodes 304 (which may correspond to the gate electrodes 204) on the gate dielectric layers 302. Source/drain regions 306 (which may correspond to active regions in the fin structures 202) are disposed in the substrate 350 on opposite sides of the gate dielectric layers 302 and the gate electrodes 304. Gate spacers 308 are formed along sidewalls of the gate dielectric layers 302 and separate the source/drain regions 306 from the gate electrodes 304 by appropriate lateral distances. The transistors may comprise fin field effect transistors (FinFETs), nanostructure (e.g., nanosheet, nanowire, gate-all-around, or the like) FETS (nano-FETs), planar FETs, the like, or combinations thereof, and may be formed by gate-first processes or gate-last processes.

A first ILD 310 surrounds and isolates the source/drain regions 306, the gate dielectric layers 302, and the gate electrodes 304 and a second ILD 312 is over the first ILD 310. Source/drain contacts 314 (which may correspond to the source/drain contacts 58, 206, 208, 210, and/or 212) extend through the second ILD 312 and the first ILD 310 and are electrically coupled to the source/drain regions 306 and gate contacts 316 (which may correspond to the gate contacts 56, 214, and/or 216) extend through the second ILD 312 and are electrically coupled to the gate electrodes 304.

An interconnect structure 320 (which may correspond to the levels M0-M4 and via_0-via_4) including one or more stacked dielectric layers 324 and conductive features 322 formed in the one or more dielectric layers 324 is over the second ILD 312, the source/drain contacts 314, and the gate contacts 316. The interconnect structure 320 may be electrically coupled to the gate contacts 316 and the source/drain contacts 314 to form functional circuits. In some embodiments, the functional circuits formed by the interconnect structure 320 may comprise memory circuits. In some embodiments, additional functional circuits, such as logic circuits, sense amplifiers, controllers, input/output circuits, image sensor circuits, the like, or combinations thereof may further be included in the interconnect structure 320. The interconnect structure 320 may be formed over a front-side of the substrate 350 and may therefore be referred to as a front-side interconnect structure. Although the interconnect structure 320 is illustrated as including four layers of conductive vias and conductive lines (e.g., levels M0-M4 and via_0-via_4), any number of layers of conductive vias and conductive lines may be included in the interconnect structure 320.

A bonding layer 330 is formed on the interconnect structure 320 and is used to bond the semiconductor device 300 to external devices. Bond pads 332 are formed in the bonding layer 330. The bonding layer 330 may be an oxide layer, such as silicon oxide (e.g., an HDP oxide or the like), silicon oxynitride, or the like. The bonding layer 330 may be deposited on using, for example, chemical vapor deposition (CVD), atomic layer deposition (ALD), physical vapor deposition (PVD), thermal oxidation, or the like. Other suitable materials may be used for the bonding layer 330. The bonding layer 330 may be used in subsequent dielectric-to-dielectric bonding processes, such as processes used to bond a circuitry device to the semiconductor device 300 (e.g., a memory device).

In some embodiments, the bond pads 332 may be formed by forming recesses in the bonding layer 330. The recesses may be formed by etching, milling, laser techniques, a combination thereof, or the like. A liner layer may be formed in the recesses, such as by thermal oxidation, ALD, CVD, or the like. The liner layer may include oxides, such as silicon oxide, silicon oxynitride, or the like. A barrier layer and/or an adhesion layer may be conformally deposited in the recesses, such as by CVD, ALD, PVD, a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the liner layer, such as portions extending along top surfaces of the bonding layer 330 are removed from the surfaces of the bonding layer 330 by a planarization process, such as a chemical-mechanical polish (CMP), a grinding process, an etch-back process, or the like. Remaining portions of the liner layer, the barrier layer, the adhesion layer, and/or the conductive fill material form the bond pads 332.

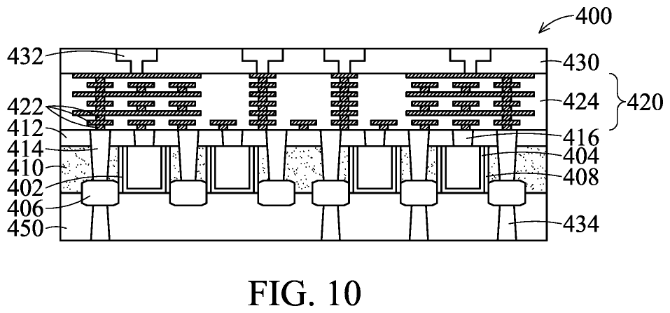

FIG. 10 illustrates a cross-sectional view of a semiconductor device 400. The semiconductor device 400 may be a circuitry device. In some embodiments, the semiconductor device 400 may comprise a logic device (e.g., central processing units (CPU), a graphics processing unit (GPU), a system-on-a-chip (SoC), an application processor (AP), a field-programmable gate array (FPGA), a microcontroller, or the like), a peripheral device (e.g., an input/output device or the like), a power management device (e.g., a power management integrated circuit (PMIC) device), a radio frequency (RF) device, a sensor device, a micro-electro-mechanical-system (MEMS) device, a signal processing device (e.g., a digital signal processing (DSP) device), a front-end device (e.g., an analog front-end (AFE) device), the like, or a combination thereof. As will be discussed below, the semiconductor device 400 may be bonded to the semiconductor device 300 (e.g., the memory array 100) and may be used to perform read/write operations and the like on the semiconductor device 300.

The semiconductor device 400 may include circuits formed on a substrate 450. The substrate 450 may be a semiconductor substrate, such as a bulk semiconductor, a semiconductor-on-insulator (SOI) substrate, or the like, which may be doped (e.g., with a p-type or an n-type dopant) or un-doped. The substrate 450 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or a glass substrate. Other substrates, such as multi-layered or gradient substrates may also be used. In some embodiments, the semiconductor material of the substrate 450 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The circuits formed on the substrate 450 may include transistors at a top surface of the substrate 450. The transistors may include gate dielectric layers 402 on top surfaces of the substrate 450 and gate electrodes 404 on the gate dielectric layers 402. Source/drain regions 406 are disposed in the substrate 450 on opposite sides of the gate dielectric layers 402 and the gate electrodes 404. Gate spacers 408 are formed along sidewalls of the gate dielectric layers 402 and separate the source/drain regions 406 from the gate electrodes 404 by appropriate lateral distances. The transistors may comprise FinFETs, nanostructure FETS, planar FETs, the like, or combinations thereof, and may be formed by gate-first processes or gate-last processes.

A first ILD 410 surrounds and isolates the source/drain regions 406, the gate dielectric layers 402, and the gate electrodes 404 and a second ILD 412 is over the first ILD 410. Source/drain contacts 414 extend through the second ILD 412 and the first ILD 410 and are electrically coupled to the source/drain regions 406 and gate contacts 416 extend through the second ILD 412 and are electrically coupled to the gate electrodes 404.

An interconnect structure 420 including one or more stacked dielectric layers 424 and conductive features 422 formed in the one or more dielectric layers 424 is over the second ILD 412, the source/drain contacts 414, and the gate contacts 416. The interconnect structure 420 may be electrically coupled to the gate contacts 416 and the source/drain contacts 414 to form functional circuits. In some embodiments, the functional circuits formed by the interconnect structure 420 may comprise logic circuits, memory circuits, sense amplifiers, controllers (e.g., word line drivers, bit line drivers, and the like), input/output circuits, image sensor circuits, the like, or combinations thereof. In some embodiments, the functional circuits may include decoders, processors, multiplexors, controllers, sense amplifiers, and the like and may be used to provide read/write operations and otherwise control the semiconductor device 300 which is subsequently bonded to the interconnect structure 420. Although FIG. 10 discusses transistors formed over the substrate 450, other active devices (e.g., diodes or the like) and/or passive devices (e.g., capacitors, resistors, or the like) may also be formed as part of the functional circuits. The interconnect structure 420 may be formed over a front-side of the substrate 450 and may therefore be referred to as a front-side interconnect structure. Although the interconnect structure 420 is illustrated as including six layers of conductive vias and conductive lines (e.g., levels M0-M6 and via_0-via_6), any number of layers of conductive vias and conductive lines may be included in the interconnect structure 420.

Through substrate vias 434 may be formed through the substrate 450 to the source/drain regions 406. The through substrate vias 434 may be formed by patterning trenches in the substrate 450 through a combination of photolithography and etching. The etching may be any acceptable etching processes, such as wet or dry etching, reactive ion etching (RIE), neutral beam etching (NBE), the like, or a combination thereof. The etching may be anisotropic. The trenches may extend through the substrate 450 to expose surfaces of the source/drain regions 406. The through substrate vias 434 may include one or more layers, such as barrier layers, diffusion layers, and fill materials. The through substrate vias 434 may be electrically coupled to the source/drain regions 406. In some embodiments, silicide regions (not separately illustrated) may be formed in the trenches adjacent the source/drain regions 406 and the through substrate vias 434 may be coupled to the source/drain regions 406 through the silicide regions. The through substrate vias 434 may include tungsten, ruthenium, cobalt, copper, titanium, titanium nitride, tantalum, tantalum nitride, molybdenum, nickel, combinations thereof, or the like. A planarization process, such as a CMP, may be performed to remove excess material from surfaces of the substrate 450 after depositing the material of the through substrate vias 434.

A bonding layer 430 is formed on the interconnect structure 420 and is used to bond the semiconductor device 400 to the semiconductor device 300. Bond pads 432 are formed in the bonding layer 430. The bonding layer 430 may be an oxide layer, such as silicon oxide (e.g., an HDP oxide or the like), silicon oxynitride, or the like. The bonding layer 430 may be deposited on using, for example CVD, ALD, PVD, thermal oxidation, or the like. Other suitable materials may be used for the bonding layer 430. The bonding layer 430 may be used in subsequent dielectric-to-dielectric bonding processes, such as processes used to bond the semiconductor device 400 (e.g., a circuitry device) to a semiconductor device 300 (e.g., a memory device).

In some embodiments, the bond pads 432 may be formed by forming recesses in the bonding layer 430. The recesses may be formed by etching, milling, laser techniques, a combination thereof, or the like. A liner layer may be formed in the recesses, such as by thermal oxidation, ALD, CVD, or the like. The liner layer may include oxides, such as silicon oxide, silicon oxynitride, or the like. A barrier layer and/or an adhesion layer may be conformally deposited in the recesses, such as by CVD, ALD, PVD, a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the liner layer, such as portions extending along top surfaces of the bonding layer 430 are removed from the surfaces of the bonding layer 430 by a planarization process, such as a chemical-mechanical polish (CMP), a grinding process, an etch-back process, or the like. Remaining portions of the liner layer, the barrier layer, the adhesion layer, and/or the conductive fill material form the bond pads 432.

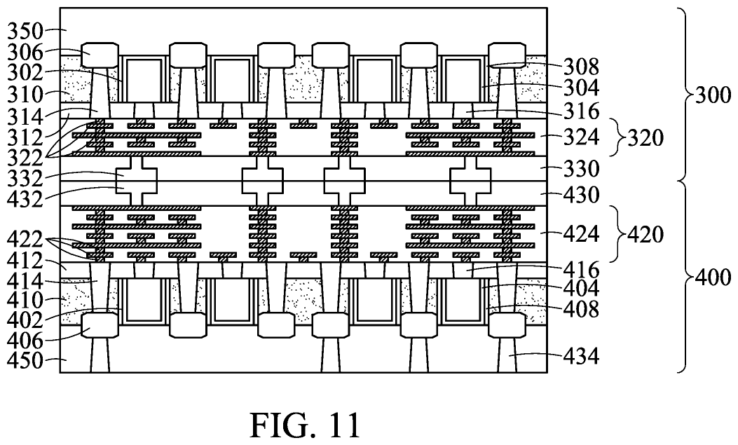

In FIG. 11, a semiconductor device 300 is bonded to a semiconductor device 400. In the embodiment of FIG. 11, a front-side of the semiconductor device 300 is bonded to a front-side of the semiconductor device 400. In the illustrated embodiment, the semiconductor device 300 is bonded to the semiconductor device 400 by hybrid bonding. The bonding layer 330 of the semiconductor device 300 is bonded to the bonding layer 430 of the semiconductor device 400 through dielectric-to-dielectric bonding, without using any adhesive material (e.g., die attach film). The bond pads 332 of the semiconductor device 300 are bonded to the bond pads 432 of the semiconductor device 400 through metal-to-metal bonding, without using any eutectic material (e.g., solder). The bonding may include a pre-bonding and an annealing. During the pre-bonding, a small pressing force is applied to press the semiconductor device 300 against the semiconductor device 400. The pre-bonding is performed at a low temperature, such as room temperature, such as a temperature in the range of about 15° C. to about 30° C. The bonding strength is then improved in a subsequent annealing step, in which the bonding layer 430 and the bonding layer 330 are annealed at a high temperature, such as a temperature in the range of about 100° C. to about 400° C. After the annealing, bonds, such as fusions bonds, are formed bonding the bonding layer 430 and the bonding layer 330. For example, the bonds can be covalent bonds between the bonding layer 430 and the bonding layer 330. The bond pads 432 and the bond pads 332 may be in physical contact after the pre-bonding, or may expand to be brought into physical contact during the annealing. Further, during the annealing, the material of the bond pads 432 and the bond pads 332 (e.g., copper) intermingles, so that metal-to-metal bonds are formed. Hence, the resulting bonds between the semiconductor device 300 and the semiconductor device 400 are hybrid bonds that include both dielectric-to-dielectric bonds and metal-to-metal bonds.

In some embodiments, the semiconductor device 300 and the semiconductor device 400 may be wafers, which include multiple integrated circuits that will subsequently be diced. In some embodiments, the semiconductor device 300 and/or the semiconductor device 400 are diced before bonding and one or more semiconductor dies may be bonded to the semiconductor device 300 or the semiconductor device 400. The semiconductor device 300 and/or the semiconductor device 400 may be diced before or after bonding. In embodiments in which the semiconductor device 300 and the semiconductor device 400 are diced after bonding, the semiconductor device 300 and the semiconductor device 400 may be diced simultaneously. As such, the semiconductor device 300 may be bonded to the semiconductor device 400 through wafer-to-wafer bonding (e.g., both the semiconductor device 300 and the semiconductor device 400 diced after bonding), die-to-die bonding (e.g., both the semiconductor device 300 and the semiconductor device 400 are diced before bonding), or die-to-wafer bonding (e.g., the semiconductor device 300 or the semiconductor device 400 are diced before bonding).

In some embodiments, the semiconductor device 400 may be a logic device, which includes circuits such as decoders, processors, multiplexors, controllers (e.g., word line drivers, bit line drivers, and the like), sense amplifiers, and the like. The semiconductor device 400 may provide control for reading and writing operations and the like to the semiconductor device 300 (e.g., the memory array 100). This allows the semiconductor device 300 to be free from logic circuits, which allows the semiconductor device 300 to have an increased density of SRAM cells 10. Moreover, connections between the functional circuits in the semiconductor device 400 and the memory cells (e.g., the SRAM cells 10) in the semiconductor device 300 may be shortened. This provides reduced power consumption, improved latency, and improved device performance.

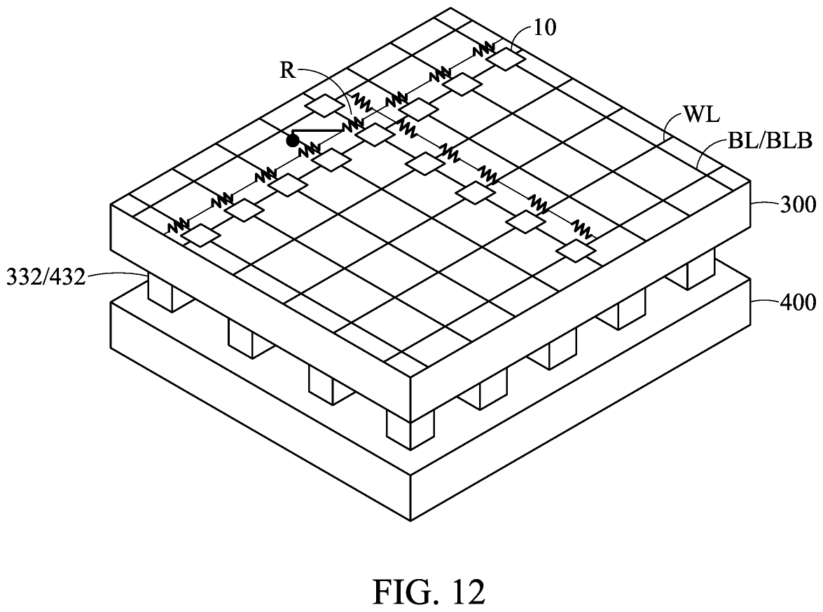

FIG. 12 is a perspective view of the semiconductor device 300 bonded to the semiconductor device 400. FIG. 12 illustrates a plurality of SRAM cells 10 of the semiconductor device 300 formed at intersections of word lines WL and pairs of bit lines BL and bit lines bar BLB. FIG. 12 illustrates that connections between the SRAM cells 10 of the semiconductor device 300 and functional circuits (e.g., word line drivers, bit line multiplexors, sense amplifiers, and the like) of the semiconductor device 400 may be made through intermediate portions of the word lines WL, the bit lines BL, and the bit lines bar BLB. This results in shorter average connections being made along the word lines WL, the bit lines BL, and the bit lines bar BLB, and reduces the number of effective resistors R through which signals travel between the SRAM cells 10 and the functional circuits. This reduces latency, reduces power consumption, and improves device performance.

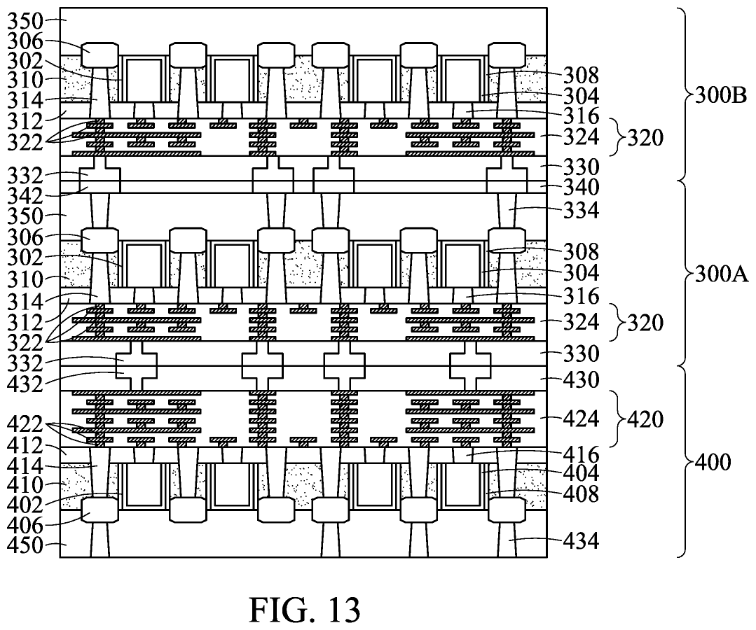

FIG. 13 illustrates an embodiment in which a semiconductor device 300A is bonded to a semiconductor device 400 and a semiconductor device 300B is bonded to the semiconductor device 300A. The semiconductor device 300A and the semiconductor device 300B may be the same as or similar to the semiconductor device 300, except that the semiconductor device 300A further includes through substrate vias 334, a bonding layer 340, and bond pads 342. The through substrate vias 334 may be formed of materials and by processes the same as or similar to the through substrate vias 434 in the semiconductor device 400, discussed above with respect to FIG. 10. The bonding layer 340 and the bond pads 342 may be formed of materials and by processes the same as or similar to the bonding layer 330 and the bond pads 332 of the semiconductor device 300, discussed above with respect to FIG. 9. The semiconductor device 300A may be bonded to the semiconductor device 400, and the semiconductor device 300B may be bonded to the semiconductor device 300A through hybrid bonding, similar to or the same as the processes used to bond the semiconductor device 300 to the semiconductor device 400 and described above with respect to FIG. 11. Any number of semiconductor devices 300 may be bonded to a semiconductor device 400 in order to increase the memory density of the packaged semiconductor device including the semiconductor device 400 and the semiconductor devices 300.

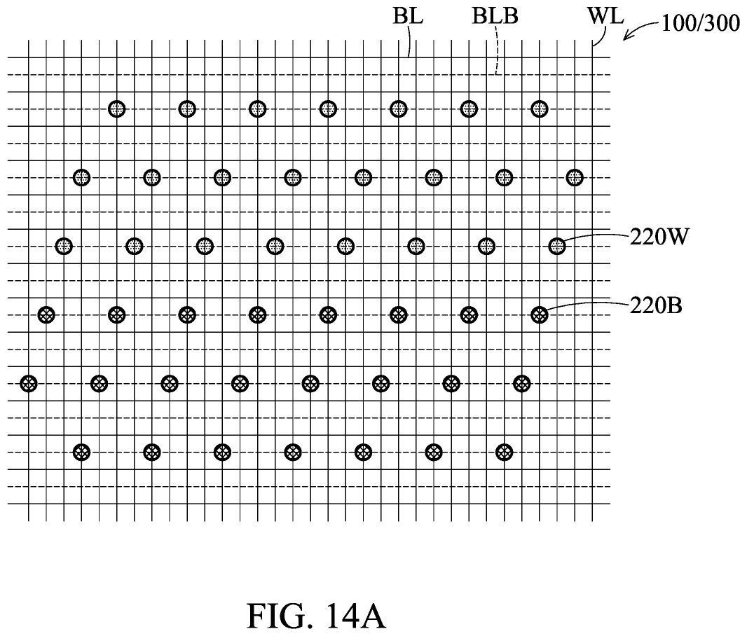

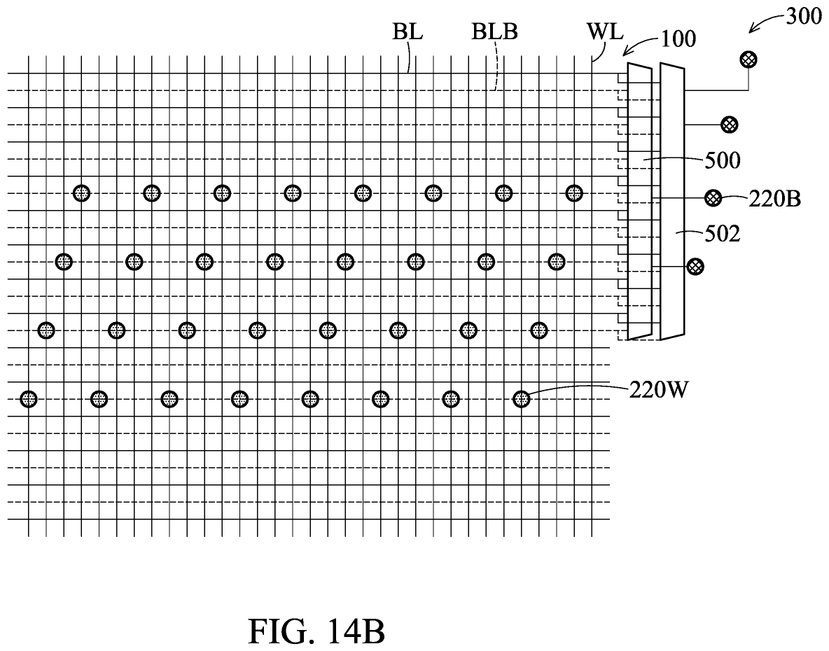

FIGS. 14A and 14B illustrate configurations of bond pads 220 on word lines WL, bit lines BL, and bit lines bar BLB in a memory array 100 of a semiconductor device 300, in accordance with some embodiments. In the embodiment illustrated in FIG. 14A, a first plurality of bond pads 220W provide connections between the word lines WL and an external device (e.g. a semiconductor device 400) and a second plurality of bond pads 220B provide connections between the bit lines BL and the bit lines bar BLB and the external device. Both the bond pads 220W and the bond pads 220B may be provided within a memory cell area of the memory array 100. Providing the bond pads 220W and the bond pads 220B within the memory cell area of the memory array 100 may increase the memory density that may be included in the memory array 100.

In the embodiment illustrated in FIG. 14B, a first plurality of bond pads 220W provide connections between the word lines WL and an external device (e.g. a semiconductor device 400). Signals for the bit lines BL and the bit lines bar BLB may be fed through a read multiplexor 500 and a write multiplexor 502 (e.g., one or more bit line multiplexors) between memory cells in the memory array 100 and the external device, and a second plurality of bond pads 220B may provide connections between the read multiplexor 500 and the write multiplexor 502 and the external device. The bond pads 220W may be provided within a memory cell area of the memory array 100, and the read multiplexor 500, the write multiplexor 502, and the bond pads 220B may be provided outside the memory cell area of the memory array 100. Providing some functional circuits in the semiconductor device 300 outside the memory array 100 may allow smaller less complex semiconductor devices 400 to be bonded to the semiconductor device 300 for providing control of reading and writing operations and the like to the semiconductor device 300 (e.g., the memory array 100).

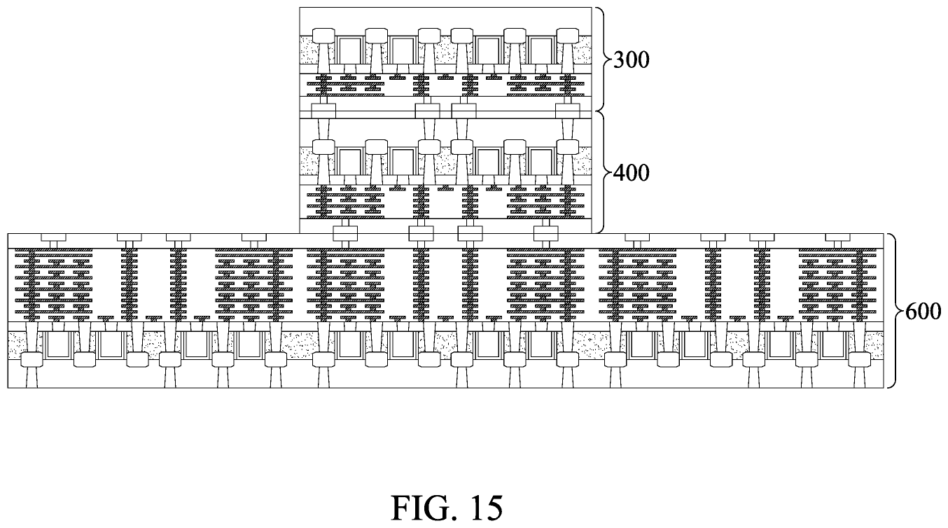

In the embodiment illustrated in FIG. 15, a semiconductor device 300 is bonded to a semiconductor device 400, which is bonded to a semiconductor device 600. The semiconductor device 600 may be the same as or similar to the semiconductor device 400, described above with respect to FIG. 10. In some embodiments, the semiconductor device 600 may be a logic device, such as a central processing unit (CPU), a graphics processing unit (GPU), a system-on-a-chip (SoCs), an application processor (AP), a field-programmable gate array (FPGA), a microcontroller, or the like. The semiconductor device 600 may include one or more caches, one or more central processing unit cores, and the like. The semiconductor device 400 may be bonded to the semiconductor device 600 through hybrid bonding, similar to or the same as the processes used to bond the semiconductor device 300 to the semiconductor device 400 and described above with respect to FIG. 11. The bonding illustrated in FIG. 15 may be used to integrate the memory array 100/semiconductor device 300 with various external devices, such as CPUs, GPUs, APs, and the like.

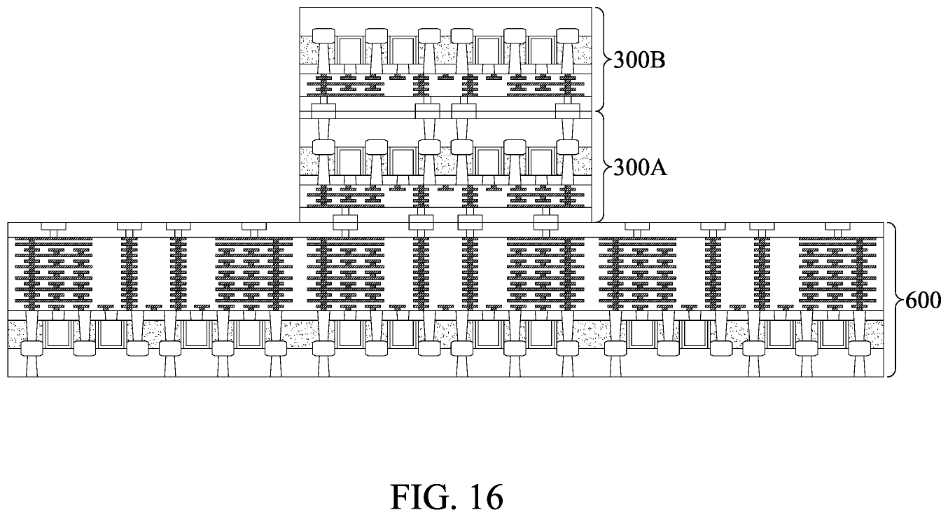

In the embodiment illustrated in FIG. 16, a semiconductor device 300B is bonded to a semiconductor device 300A, which is bonded to a semiconductor device 600. The semiconductor device 600 may be the same as or similar to the semiconductor device 400, described above with respect to FIG. 10. In some embodiments, the semiconductor device 600 may be a logic device, such as a central processing unit (CPU), a graphics processing unit (GPU), a system-on-a-chip (SoCs), an application processor (AP), a field-programmable gate array (FPGA), a microcontroller, or the like. The semiconductor device 600 may one or more central processing unit cores and the like. In some embodiments, the semiconductor device 600 may include functional circuits, as described above, and may be used to provide control of reading and writing operations and the like to the semiconductor devices 300A and 300B (e.g., the memory array 100). The semiconductor device 300A may be bonded to the semiconductor device 600 through hybrid bonding, similar to or the same as the processes used to bond the semiconductor device 300 to the semiconductor device 400 and described above with respect to FIG. 11. The bonding illustrated in FIG. 16 may be used to integrate the memory array 100/semiconductor device 300 with various external devices, such as CPUs, GPUs, APs, and the like.

Embodiments may achieve various advantages. For example, forming memory cells in a memory device, and forming functional circuits for providing control of reading and writing operations and the like to the memory device in a separate circuitry device allows for memory density in the memory device to be improved. Moreover, connections between the memory cells and the functional circuits may be shortened, and may be provided in a more flexible manner to reduce latency, reduce power consumption, and improve device performance.

In accordance with an embodiment, a semiconductor device includes a first memory die including a first memory cell electrically coupled to a first word line; a second memory cell electrically coupled to the first word line; and a first interconnect structure electrically coupled to the first word line; a circuitry die including a second interconnect structure, a first conductive feature of the first interconnect structure being bonded to a second conductive feature of the second interconnect structure through metal-to-metal bonds; and a word line driver electrically coupled to the first word line between the first memory cell and the second memory cell, the word line driver being electrically coupled to the first word line through the first interconnect structure and the second interconnect structure. In an embodiment, the semiconductor device further includes a second memory die bonded to the first memory die opposite the circuitry die, the word line driver being electrically coupled to a second word line of the second memory die. In an embodiment, a front-side of the first memory die is bonded to a front-side of the circuitry die by dielectric-to-dielectric bonds and metal-to-metal bonds, and a front-side of the second memory die is bonded to a backside of the first memory die by dielectric-to-dielectric bonds and metal-to-metal bonds. In an embodiment, the first memory cell and the second memory cell are disposed within a memory cell array, the first memory cell further includes a first bit line electrically coupled to the first memory cell, the first conductive feature is electrically coupled to the first word line, the first interconnect structure further includes a third conductive feature electrically coupled to the first bit line, the third conductive feature is bonded to the second interconnect structure through metal-to-metal bonds, and the first conductive feature and the third conductive feature are disposed within the memory cell array. In an embodiment, the first memory cell and the second memory cell are disposed within a memory cell array, the first memory cell further includes a first bit line electrically coupled to the first memory cell, the first conductive feature is electrically coupled to the first word line, the first interconnect structure further includes a third conductive feature electrically coupled to the first bit line, the third conductive feature is bonded to the second interconnect structure through metal-to-metal bonds, the first conductive feature is disposed within the memory cell array, and the third conductive feature is disposed outside the memory cell array. In an embodiment, the first memory die further includes a bit line multiplexer electrically coupled to the first bit line and the third conductive feature, the bit line multiplexer being disposed outside the memory cell array. In an embodiment, the first memory die includes a complementary field-effect transistor (CFET) memory die.

In accordance with another embodiment, a device includes a logic die including a first functional circuit on a first semiconductor substrate; a first interconnect structure on the logic die; a memory die including a second semiconductor substrate; a first memory cell on the second semiconductor substrate; a second memory cell on the second semiconductor substrate; and a bit line electrically coupled to the first memory cell and the second memory cell, the first functional circuit being electrically coupled to the bit line between the first memory cell and the second memory cell, and the first functional circuit being configured to perform a read or a write operation through the bit line; and a second interconnect structure on the memory die, the second interconnect structure being bonded to the first interconnect structure by dielectric-to-dielectric bonds and metal-to-metal bonds. In an embodiment, the first interconnect structure is on a front-side of the first semiconductor substrate, and the second interconnect structure is on a front-side of the second semiconductor substrate. In an embodiment, the device further includes a third interconnect structure on a backside of the second semiconductor substrate; and a second memory die including a fourth interconnect structure on a front-side of a third substrate, the fourth interconnect structure being bonded to the third interconnect structure by dielectric-to-dielectric bonds and metal-to-metal bonds. In an embodiment, the memory die includes a memory cell area, the first memory cell and the second memory cell are disposed within the memory cell area, the second interconnect structure includes a first plurality of bit line bond pads including a first bit line bond pad electrically coupled to the bit line, and the first plurality of bit line bond pads is disposed within the memory cell area. In an embodiment, the memory die further includes a word line electrically coupled to the first memory cell, the second interconnect structure includes a second plurality of word line bond pads including a first word line bond pad electrically coupled to the word line, and the second plurality of word line bond pads is disposed within the memory cell area. In an embodiment, the logic die further includes a second functional circuit on the first semiconductor substrate, the memory die further includes a third memory cell on the second semiconductor substrate; and a word line electrically coupled to the first memory cell and the third memory cell, the second functional circuit being electrically coupled to the word line between the first memory cell and the third memory cell. In an embodiment, the second functional circuit is a word line driver.

In accordance with yet another embodiment, a method includes providing a logic device, the logic device including a first substrate, a first device layer on the first substrate, and a first interconnect structure on the first device layer; providing a memory device, the memory device including a second substrate, a second device layer on the second substrate, and a second interconnect structure on the second device layer; depositing a first bonding layer on the first interconnect structure; depositing a second bonding layer on the second interconnect structure; and coupling the logic device to the memory device by performing dielectric-to-dielectric bonding between the first bonding layer and the second bonding layer, the logic device being configured to perform read and write operations to memory cells of the memory device. In an embodiment, the method further includes forming a first plurality of bond pads in the first bonding layer; and forming a second plurality of bond pads in the second bonding layer, coupling the logic device to the memory device further includes performing metal-to-metal bonding between the first plurality of bond pads and the second plurality of bond pads. In an embodiment, the memory device includes a plurality of memory cells in a memory cell area; a plurality of word lines electrically coupled to the memory cells; and a plurality of bit lines electrically coupled to the memory cells, the second plurality of bond pads including a first plurality of word line bond pads electrically coupled to the word lines, the second plurality of bond pads including a first plurality of bit line bond pads electrically coupled to the bit lines, and the first plurality of word line bond pads and the first plurality of bit line bond pads being formed within the memory cell area. In an embodiment, the memory device includes a plurality of memory cells in a memory cell area; a plurality of word lines electrically coupled to the memory cells; and a plurality of bit lines electrically coupled to the memory cells, the second plurality of bond pads including a first plurality of word line bond pads electrically coupled to the word lines, the second plurality of bond pads including a first plurality of bit line bond pads electrically coupled to the bit lines, the first plurality of word line bond pads being formed within the memory cell area, and the first plurality of bit line bond pads being formed outside the memory cell area. In an embodiment, the method further includes providing a second memory device, the second memory device including a third substrate, a third device layer on the third substrate, and a third interconnect structure on the third device layer; depositing a third bonding layer on the second substrate opposite the second interconnect structure; depositing a fourth bonding layer on the third interconnect structure; and coupling the second memory device to the memory device by performing dielectric-to-dielectric bonding between the fourth bonding layer and the third bonding layer, the logic device being configured to perform read and write operations to second memory cells of the second memory device. In an embodiment, a plurality of logic devices are provided on a first wafer including the first substrate, a plurality of memory devices are provided on a second wafer including the second substrate, coupling the logic device to the memory device includes wafer-to-wafer bonding, and the method further includes dicing the first wafer and the second wafer to form a first logic die including the logic device and a first memory die including the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first memory die comprising:
a first memory cell electrically coupled to a first word line;
a second memory cell electrically coupled to the first word line; and
a first interconnect structure electrically coupled to the first word line;
a circuitry die comprising:
a second interconnect structure, wherein a first conductive feature of the first interconnect structure is bonded to a second conductive feature of the second interconnect structure through metal-to-metal bonds; and
a word line driver electrically coupled to the first word line between the first memory cell and the second memory cell, wherein the word line driver is electrically coupled to the first word line through the first interconnect structure and the second interconnect structure.

2. The semiconductor device of claim 1, further comprising a second memory die bonded to the first memory die opposite the circuitry die, wherein the word line driver is electrically coupled to a second word line of the second memory die.

3. The semiconductor device of claim 2, wherein a front-side of the first memory die is bonded to a front-side of the circuitry die by dielectric-to-dielectric bonds and metal-to-metal bonds, and wherein a front-side of the second memory die is bonded to a backside of the first memory die by dielectric-to-dielectric bonds and metal-to-metal bonds.

4. The semiconductor device of claim 1, wherein the first memory cell and the second memory cell are disposed within a memory cell array, wherein the first memory cell further comprises a first bit line electrically coupled to the first memory cell, wherein the first conductive feature is electrically coupled to the first word line, wherein the first interconnect structure further comprises a third conductive feature electrically coupled to the first bit line, wherein the third conductive feature is bonded to the second interconnect structure through metal-to-metal bonds, and wherein the first conductive feature and the third conductive feature are disposed within the memory cell array.

5. The semiconductor device of claim 1, wherein the first memory cell and the second memory cell are disposed within a memory cell array, wherein the first memory cell further comprises a first bit line electrically coupled to the first memory cell, wherein the first conductive feature is electrically coupled to the first word line, wherein the first interconnect structure further comprises a third conductive feature electrically coupled to the first bit line, wherein the third conductive feature is bonded to the second interconnect structure through metal-to-metal bonds, wherein the first conductive feature is disposed within the memory cell array, and wherein the third conductive feature is disposed outside the memory cell array.

6. The semiconductor device of claim 5, wherein the first memory die further comprises a bit line multiplexer electrically coupled to the first bit line and the third conductive feature, wherein the bit line multiplexer is disposed outside the memory cell array.

7. The semiconductor device of claim 1, wherein the first memory die comprises a complementary field-effect transistor (CFET) memory die.

8. A device comprising:
a logic die comprising a first functional circuit on a first semiconductor substrate;
a first interconnect structure on the logic die;
a memory die comprising:
a second semiconductor substrate;
a first memory cell on the second semiconductor substrate;
a second memory cell on the second semiconductor substrate; and
a bit line electrically coupled to the first memory cell and the second memory cell, wherein the first functional circuit is electrically coupled to the bit line between the first memory cell and the second memory cell, and wherein the first functional circuit is configured to perform a read or a write operation through the bit line; and
a second interconnect structure on the memory die, wherein the second interconnect structure is bonded to the first interconnect structure by dielectric-to-dielectric bonds and metal-to-metal bonds.

9. The device of claim 8, wherein the first interconnect structure is on a front-side of the first semiconductor substrate, and wherein the second interconnect structure is on a front-side of the second semiconductor substrate.

10. The device of claim 9, further comprising:
a third interconnect structure on a backside of the second semiconductor substrate; and
a second memory die comprising a fourth interconnect structure on a front-side of a third substrate, wherein the fourth interconnect structure is bonded to the third interconnect structure by dielectric-to-dielectric bonds and metal-to-metal bonds.

11. The device of claim 8, wherein the memory die comprises a memory cell area, wherein the first memory cell and the second memory cell are disposed within the memory cell area, wherein the second interconnect structure comprises a first plurality of bit line bond pads comprising a first bit line bond pad electrically coupled to the bit line, and wherein the first plurality of bit line bond pads is disposed within the memory cell area.

12. The device of claim 11, wherein the memory die further comprises a word line electrically coupled to the first memory cell, wherein the second interconnect structure comprises a second plurality of word line bond pads comprising a first word line bond pad electrically coupled to the word line, and wherein the second plurality of word line bond pads is disposed within the memory cell area.

13. The device of claim 8, wherein the logic die further comprises a second functional circuit on the first semiconductor substrate, wherein the memory die further comprises:
a third memory cell on the second semiconductor substrate; and
a word line electrically coupled to the first memory cell and the third memory cell, wherein the second functional circuit is electrically coupled to the word line between the first memory cell and the third memory cell.

14. The device of claim 13, wherein the second functional circuit is a word line driver.

15. A method comprising:
providing a logic device, the logic device comprising a first substrate, a first device layer on the first substrate, and a first interconnect structure on the first device layer;
providing a memory device, the memory device comprising a second substrate, a second device layer on the second substrate, and a second interconnect structure on the second device layer;
depositing a first bonding layer on the first interconnect structure;
depositing a second bonding layer on the second interconnect structure; and
coupling the logic device to the memory device by performing dielectric-to-dielectric bonding between the first bonding layer and the second bonding layer, wherein the logic device is configured to perform read and write operations to memory cells of the memory device.

16. The method of claim 15, further comprising:
forming a first plurality of bond pads in the first bonding layer; and
forming a second plurality of bond pads in the second bonding layer, wherein coupling the logic device to the memory device further comprises performing metal-to-metal bonding between the first plurality of bond pads and the second plurality of bond pads.

17. The method of claim 16, wherein the memory device comprises:
a plurality of memory cells in a memory cell area;
a plurality of word lines electrically coupled to the memory cells; and
a plurality of bit lines electrically coupled to the memory cells, wherein the second plurality of bond pads comprises a first plurality of word line bond pads electrically coupled to the word lines, wherein the second plurality of bond pads comprises a first plurality of bit line bond pads electrically coupled to the bit lines, and wherein the first plurality of word line bond pads and the first plurality of bit line bond pads are formed within the memory cell area.

18. The method of claim 16, wherein the memory device comprises:
a plurality of memory cells in a memory cell area;
a plurality of word lines electrically coupled to the memory cells; and
a plurality of bit lines electrically coupled to the memory cells, wherein the second plurality of bond pads comprises a first plurality of word line bond pads electrically coupled to the word lines, wherein the second plurality of bond pads comprises a first plurality of bit line bond pads electrically coupled to the bit lines, wherein the first plurality of word line bond pads is formed within the memory cell area, and wherein the first plurality of bit line bond pads is formed outside the memory cell area.

19. The method of claim 15, further comprising:
providing a second memory device, the second memory device comprising a third substrate, a third device layer on the third substrate, and a third interconnect structure on the third device layer;
depositing a third bonding layer on the second substrate opposite the second interconnect structure;
depositing a fourth bonding layer on the third interconnect structure; and
coupling the second memory device to the memory device by performing dielectric-to-dielectric bonding between the fourth bonding layer and the third bonding layer, wherein the logic device is configured to perform read and write operations to second memory cells of the second memory device.

20. The method of claim 15, wherein a plurality of logic devices are provided on a first wafer comprising the first substrate, wherein a plurality of memory devices are provided on a second wafer comprising the second substrate, wherein coupling the logic device to the memory device comprises wafer-to-wafer bonding, and wherein the method further comprises dicing the first wafer and the second wafer to form a first logic die comprising the logic device and a first memory die comprising the memory device.
